(19) United States
(12) Patent Application Publication
(10) Pub. No.: US 2016/0325984 A1
(43) Pub. Date: Nov. 10, 2016

(54) CHIP SCALE PACKAGE

(71) Applicant: InvenSense, Inc., San Jose, CA (US)

(72) Inventors: Michael DUEWEKE, Campbell, CA (US); Stephen LLOYD, Los Altos, CA (US)

(21) Appl. No.: 14/705,616

(22) Filed: May 6, 2015

(51) Int. Cl. B81B 7/00; B81C 1/00

(52) U.S. Cl. CPC B81B 7/0051; B81C 1/00301; B81C 1/00325; B81B 7/0006; B81B 7/008

(57) ABSTRACT

A system and method for providing a chip scale package of a MEMS device are disclosed. The system is a chip scale package (CSP) that comprises a substrate, a cap substrate, a MEMS device substrate bonded to and located between both the substrate and the cap substrate, at least one solder ball, and a via support structure coupled to both the at least one solder ball and the substrate, wherein the MEMS device substrate and the cap substrate are mechanically isolated from the at least one solder ball. The method comprises coupling a MEMS device substrate to a cap substrate, forming at least one insulated via through both the MEMS device substrate and the cap substrate, providing singulation of the cap substrate to provide a via support structure that surrounds the at least one insulated via, and coupling at least one solder ball to the via support structure.

### FIELD OF THE INVENTION

The present invention relates to microelectromechanical systems (MEMS) sensors, and more particularly, to MEMS sensor packaging.

### BACKGROUND

Microelectromechanical system (MEMS) sensors/devices require packaging. Conventional MEMS sensor packaging is thick and does not adequately protect the MEMS sensor/device from damage due to external handling and performance degradation from shear stress. Therefore, there is a strong need for a solution that overcomes the aforementioned issues. The present invention addresses such a need.

### SUMMARY OF THE INVENTION

A system and method for providing a chip scale package of a MEMS device are disclosed. In a first aspect, the system is a chip scale package (CSP) that comprises a substrate, a cap substrate, a MEMS device substrate bonded to and located between both the substrate and the cap substrate, at least one solder ball, and a via support structure coupled to both the at least one solder ball and the substrate, wherein the MEMS device substrate and the cap substrate are mechanically isolated from the at least one solder ball.

In a second aspect, the method comprises coupling a MEMS device substrate to a cap substrate, forming at least one insulated via through both the MEMS device substrate and the cap substrate, singulating the cap substrate and the MEMS device substrate to provide a via support structure that surrounds the at least one insulated via, and coupling at least one solder ball to the via support structure.

### BRIEF DESCRIPTION OF THE DRAWINGS

The accompanying figures illustrate several embodiments of the invention and, together with the description, serve to explain the principles of the invention. One of ordinary skill in the art readily recognizes that the embodiments illustrated in the figures are merely exemplary, and are not intended to limit the scope of the present invention.

FIG. 1 illustrates a cross-section view of a chip scale package of a MEMS device in accordance with an embodiment.

FIG. 2 illustrates a cross-section view of a complementary metal-oxide-semiconductor (CMOS) substrate in accordance with an embodiment.

FIG. 3 illustrates a cross-section view of a cap substrate in accordance with an embodiment.

FIG. 4 illustrates a cross-section view of a cap substrate in accordance with an embodiment.

FIG. 5 illustrates a cross-section view of a cap substrate coupled to a MEMS device substrate in accordance with an embodiment.

FIG. 6 illustrates a cross-section view of a cap substrate coupled to a MEMS device substrate with via holes in accordance with an embodiment.

FIG. 7 illustrates a cross-section view of a liner layer within the via holes in accordance with an embodiment.

FIG. 8 illustrates a cross-section view of a conducting material within the via holes in accordance with an embodiment.

FIG. 9 illustrates a cross-section view of a MEMS device substrate 904 with a plurality of protrusions in accordance with an embodiment.

FIG. 10 illustrates a cross-section view of a bonding material provided on a plurality of protrusions in accordance with an embodiment.

FIG. 11 illustrates a cross-section view of a MEMS device substrate that has been patterned and etched to remove areas in accordance with an embodiment.

FIG. 12 illustrates a cross-section view of a substrate bonded to both the MEMS device substrate and the cap substrate in accordance with an embodiment.

FIG. 13 illustrates a cross-section view of a substrate and a cap substrate that are thinned in accordance with an embodiment.

FIG. 14 illustrates a cross-section view of preparing the cap substrate for solder ball attachment in accordance with an embodiment.

FIG. 15 illustrates a cross-section view of singulation of the cap substrate in accordance with an embodiment.

FIG. 16 illustrates a cross-section view of solder ball attachment in accordance with an embodiment.

FIG. 17 illustrates a cross-section view of singulation of the substrate and the chip scale package in accordance with an embodiment.

FIG. 18 illustrates a cross-section view of attaching the chip scale package to a printed circuit board in accordance with an embodiment.

FIG. 19 illustrates a method for providing a chip scale package of a MEMS device in accordance with an embodiment.

### DETAILED DESCRIPTION

The present invention relates to microelectromechanical systems (MEMS) sensors, and more particularly, to MEMS sensor packaging. The following description is presented to enable one of ordinary skill in the art to make and use the invention and is provided in the context of a patent application and its requirements. Various modifications to the preferred embodiment and the generic principles and features described herein will be readily apparent to those skilled in the art. Thus, the present invention is not intended to be limited to the embodiments shown but is to be accorded the widest scope consistent with the principles and features described herein.

Micro-Electro-Mechanical Systems (MEMS) refers to a class of devices fabricated using semiconductor-like processes and exhibiting mechanical characteristics such as the ability to move or deform. MEMS often, but not always, interact with electrical signals. A MEMS device (or MEMS sensor) may refer to a semiconductor device implemented as a microelectromechanical system. A MEMS device includes mechanical elements and optionally includes electronics for sensing. MEMS devices include but are not limited to gyroscopes, accelerometers, magnetometers, and pressure sensors.

A system and method in accordance with the present invention provides a chip scale package for MEMS sensors/devices that provides for improved protection and reduced stress on the MEMS device by mechanically isolating the cap wafer (substrate) from external stress and handling. The chip scale package provided by the system and method also provide improved MEMS device performance under shear stress because the cap wafer (substrate) is not anchored to the solder balls that experience shear.

In one embodiment, the chip scale package is provided for a MEMS device. The chip scale package includes a substrate, a cap wafer (substrate), a MEMS device substrate comprising at least one MEMS device, a via support structure (or through wafer vias), and solder balls bonded to the substrate by the via support structure. The chip scale package provides enhanced protection to the at least one MEMS device (that is sealed between the cap substrate and the substrate and not in contact with the solder balls) from handling and a reduction of shear stress on the MEMS device.

To describe the features of the present invention in more detail, refer now to the following description in conjunction with the accompanying Figures.

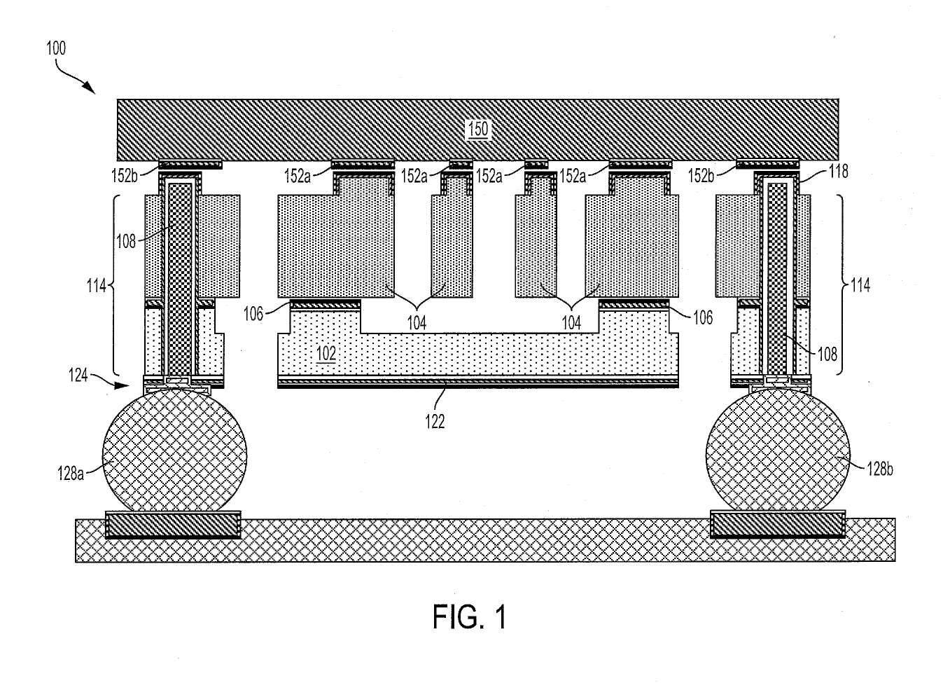

FIG. 1 illustrates a cross-section view of a chip scale package 100 of a MEMS device in accordance with an embodiment. The chip scale package 100 includes a cap wafer (substrate) 102 coupled or bonded to a MEMS device 104 (formed from a MEMS device substrate). In one embodiment, the cap substrate 102 is bonded to the MEMS device 104 using a bonding material 106 including but not limited to silicon dioxide, TetraEthyl OrthoSilicate (TEOS), epoxy, and metal eutectic. The chip scale package 100 further includes a substrate 150 and the MEMS device 104 is also bonded to a substrate 150.

In one embodiment, the substrate 150 is a semiconductor wafer including but not limited to a complementary metal-oxide-semiconductor (CMOS) substrate (circuit wafer). In one embodiment, the MEMS device 104 is bonded to the substrate 150 using a bonding material 118 and a first set of electrodes 152a (e.g., metal electrodes). The rest of the MEMS device substrate (near the via support structures 114) is bonded to the substrate 150 using the bonding material 118 and a second set of electrodes 152b (e.g., metal electrodes). The bonding materials 106 and 118 can either be the same type of bonding material or different bonding materials.

The MEMS device 104 is sealed within the cap substrate 102 and the substrate 150. The chip scale package 100 further includes two via support structures 114 that each comprise a through-wafer via 108 (also referred to as an insulated, conducting via). Each via support structure 114 comprises a portion of the cap substrate material and a portion of the MEMS device substrate material. The two via support structures 114 are on opposite lateral ends or sides of the chip scale package 100. Each via support structure 114 electrically connects the substrate 150 via the second set of electrodes 152b to one of the two or more solder balls 128a-b. In one embodiment, the chip scale package 100 only includes one solder ball and in another embodiment, the chip scale package 100 includes two or more solder balls based upon the configuration of the MEMS device.

One of the solder balls 128a-b is bonded to one of the via support structures 114 (and the other solder ball is bonded to the other via support structure) by using a first layer 122 that comprises a solder protection layer and by using a second layer 124 that comprises a solder adhesion layer. In the chip scale package 100, the MEMS device 104 and the cap substrate 102 are mechanically isolated from the solder balls 128a-b that are attached to the via support structures 114 which results in additional protection of the MEMS device 104 and a reduction of shear stress (that the solder balls 128a-b experience) on the MEMS device 104.

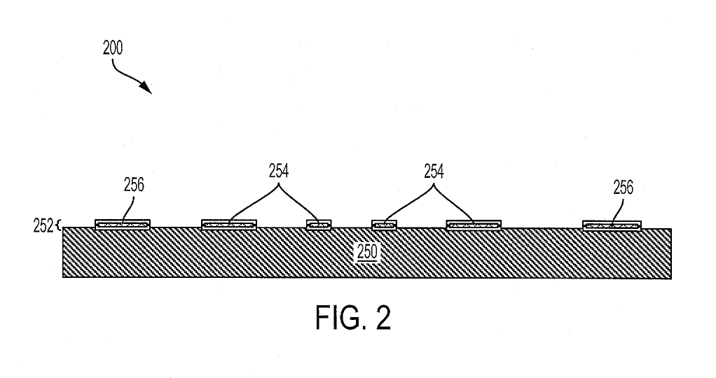

One of ordinary skill in the art readily recognizes that the chip scale package 100 of the MEMS device 104 can be manufactured and constructed using a plurality of varying steps and that would be within the spirit and scope of the present invention. FIGS. 2-18 describe one embodiment for the manufacturing of the chip scale package 100 of the MEMS device 104 and each of the manufacturing process steps listed can be done in slightly different orders than described below.

In one embodiment, the manufacturing process of the chip scale package 100 starts with providing a first substrate as a complementary metal-oxide-semiconductor (CMOS) substrate. FIG. 2 illustrates a cross-section view 200 of a substrate 250 in accordance with an embodiment. In one embodiment, the substrate 250 is a CMOS substrate. The substrate 250 is a similar structure to the substrate 150 of the chip scale package 100 illustrated by FIG. 1. The substrate 250 is coupled to a top layer 252 that comprises a first section of electrodes 254 and a second section of electrodes 256. In one embodiment, the top layer 252 is a top metal layer comprising a first and second section of metal electrodes. In one embodiment, the substrate 250 comprises CMOS circuitry fabricated on a silicon wafer or other type of semiconductor wafer.

The substrate 250 may comprise a plurality of layers including but not limited to field effect transistors and multiple layers of metal and interlayer dielectrics (ILDs), but only the top layer 252 is shown in FIG. 2. In one embodiment, the first section of electrodes 254 of the top layer 252 includes a MEMS seal ring and internal bond pads and the second section of electrodes 256 of the top layer 252 includes external bond pads or bond pads for a CMOS circuit interface. In one embodiment, the top layer 252 comprises a plurality of conductive metals that enable an electrical connection to be created between the substrate 250 and solder balls (not shown in FIG. 2) of the chip scale package 100.

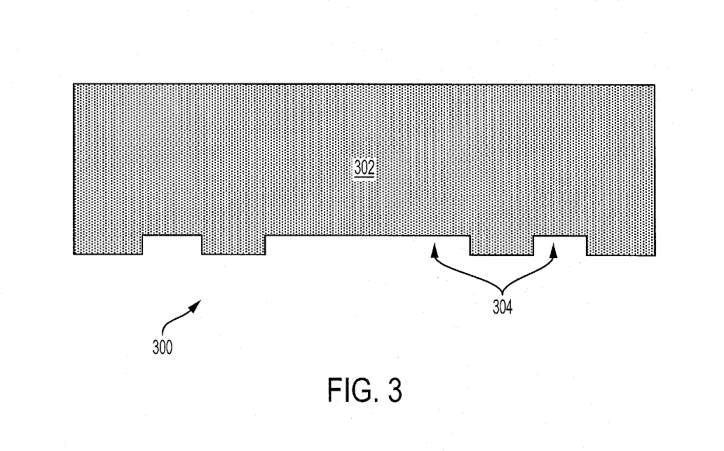

After the first substrate is provided, the manufacturing process of the chip scale package 100 provides another substrate as a cap substrate. FIG. 3 illustrates a cross-section view 300 of a cap substrate 302 in accordance with an embodiment. The cap substrate 302 is a similar structure to the cap substrate 102 of the chip scale package 100 illustrated by FIG. 1. The cap substrate 302 is manufactured with a plurality of recesses 304 etched into one side of the cap substrate 302. In one embodiment, the plurality of recesses 304 are all the same size (both the depth and the width of each recess) and in another embodiment the plurality of recesses 304 are of varying size (either or both the depth and the width of each recess).

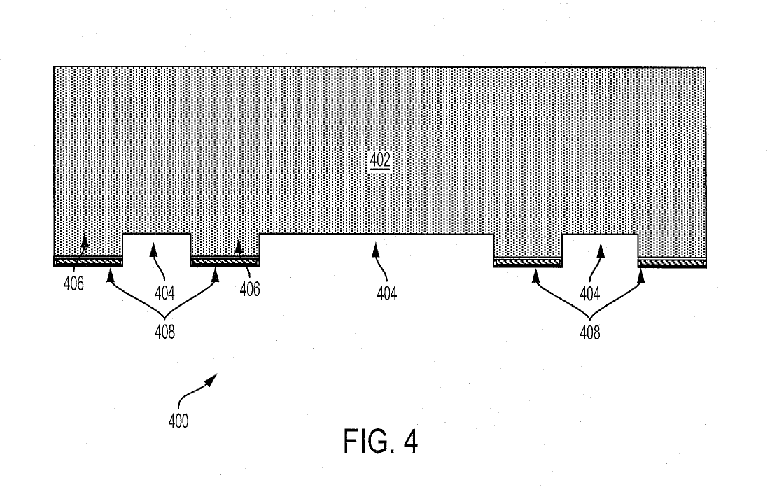

After providing both substrates, the manufacturing process of the chip scale package 100 etches the cap substrate and then grows or deposits an oxide layer onto the cap substrate. FIG. 4 illustrates a cross-section view 400 of a cap substrate 402 in accordance with an embodiment. The cap substrate 402 is a similar structure to the cap substrate 102 of the chip scale package 100 illustrated by FIG. 1.

In FIG. 4, the cap substrate 402 includes a plurality of recesses 404 and a plurality of protrusions 406 that are formed by the etching process that creates the plurality of recesses 404. In addition, the cap substrate 402 includes an oxide layer 408 that is either grown or deposited onto the cap substrate 402. In one embodiment, the oxide layer 408 is grown or deposited onto the entire surface of the cap substrate 402 and in another embodiment, the oxide layer 408 is only grown or deposited onto the plurality of protrusions 406 (as shown in FIG. 4) of the cap substrate 402.

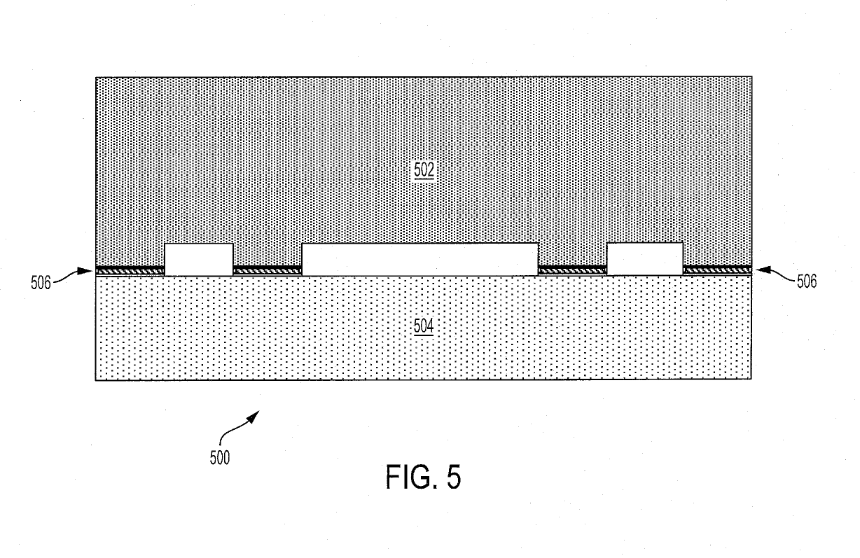

The manufacturing process of the chip scale package 100 then couples the cap and a MEMS device substrate together. FIG. 5 illustrates a cross-section view 500 of a cap substrate 502 coupled to a MEMS device substrate 504 in accordance with an embodiment. The cap substrate 502 is a similar structure to the cap substrate 102 of the chip scale package 100 illustrated by FIG. 1. The MEMS device substrate 504 is a similar structure to the MEMS device substrate 104 of the chip scale package 100 illustrated by FIG. 1. In FIG. 5, the cap substrate 502 is bonded to the MEMS device substrate 504 using an oxide layer 506. In another embodiment, the cap substrate 502 is bonded to the MEMS device substrate 504 using a variety of other bonding materials.

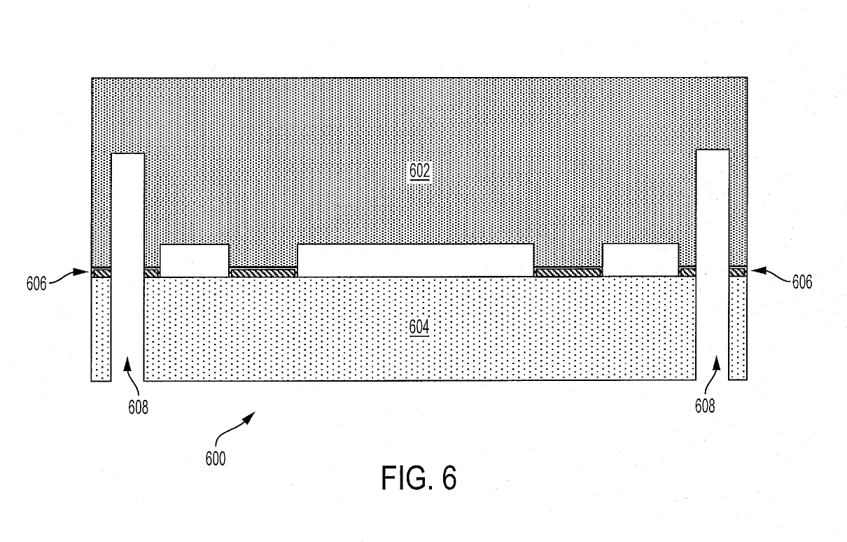

After coupling the cap and MEMS device substrates together, the manufacturing process of the chip scale package 100 etches via holes. FIG. 6 illustrates a cross-section view 600 of a cap substrate 602 coupled to a MEMS device substrate 604 with via holes 608 in accordance with an embodiment. The cap substrate 602 and the MEMS device substrate 604 are both similar structures to the cap substrate 102 and the MEMS device substrate 104 respectively of the chip scale package 100 illustrated by FIG. 1.

In FIG. 6, the cap substrate 602 is bonded to the MEMS device substrate 604 using an oxide layer 606 as seen in FIG. 5. Additionally, via holes 608 that initiate the formation of a via support structure have been etched starting with the MEMS device substrate 604, through the oxide layer 606 and through a portion of the cap substrate 602. The via holes 608 or etches can be of varying width, height, and depth but go completely through the MEMS device substrate 604 and only partially through the cap substrate 602. In one embodiment, there are two separate holes of the via holes 608 that are each etched into the substrates (as shown in FIG. 6). In another embodiment, there is only one hole etched or more than two holes etched into the substrates depending upon the desired number of via etches for the via support structure.

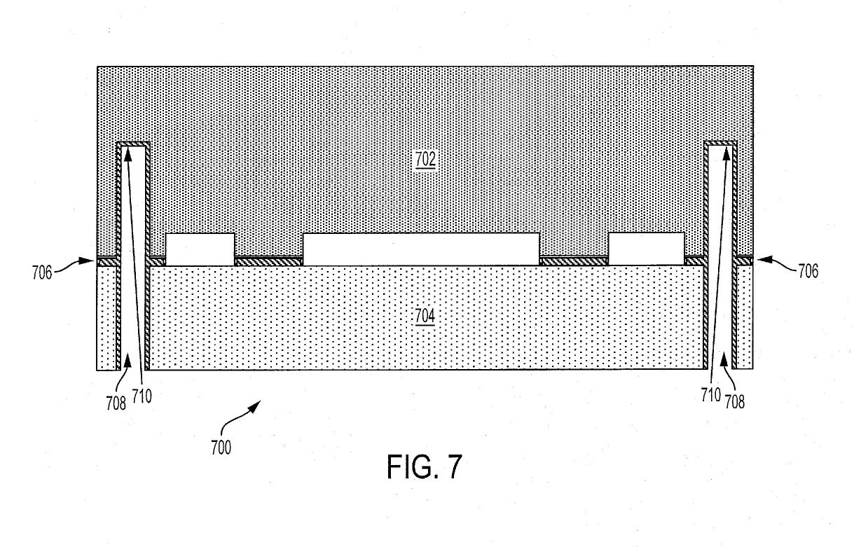

After etching the via holes, the manufacturing process of the chip scale package 100 provides a liner layer within the etched via holes. FIG. 7 illustrates a cross-section view 700 of a liner layer 710 within the via holes 708 in accordance with an embodiment. The cap substrate 702 and the MEMS device substrate 704 are both similar structures to the cap substrate 102 and the MEMS device substrate 104 respectively of the chip scale package 100 illustrated by FIG. 1.

In addition, FIG. 7 includes an oxide layer 706 that bonds the cap substrate 702 and the MEMS device substrate 704 together as well as the via holes 708 which resembles the components of FIG. 6. In addition, FIG. 7 further includes the liner layer 710 that is provided within the via holes 708. The liner layer 710 can cover the entire interior of the via holes 708 or only predetermined portions. In one embodiment, the liner layer 710 is a growth or deposition of an oxide liner layer. In another embodiment, the liner layer 710 is a different type of insulating layer.

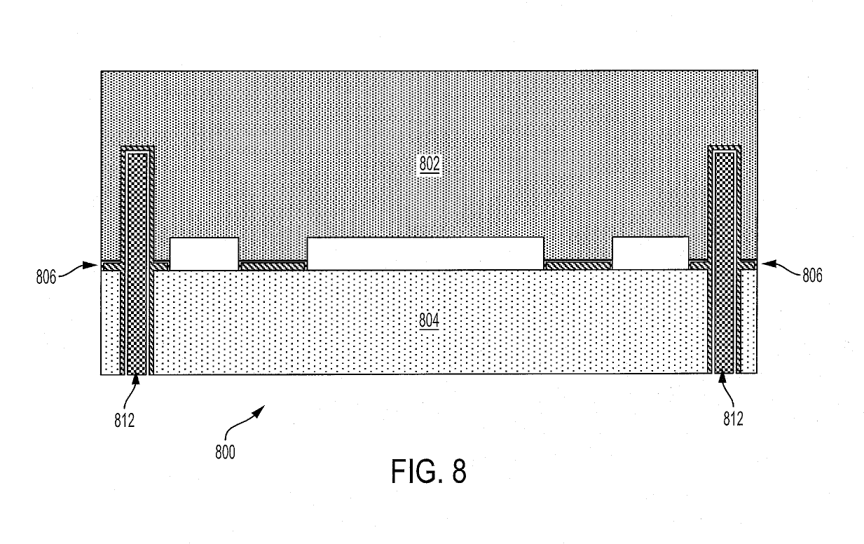

Once the liner layer is provided within the via holes, the manufacturing process of the chip scale package 100 provides a conducting material within the via holes. FIG. 8 illustrates a cross-section view 800 of a conducting material 812 within the via holes in accordance with an embodiment. FIG. 8 includes a cap substrate 802, a MEMS device substrate 804, an oxide layer 806, via holes, and a liner layer which resembles the components of FIG. 7. In addition, FIG. 8 further includes the conducting material 812 that is provided within the via holes. In one embodiment, the conducting material 812 is polysilicon and is deposited into the via support structure etches/holes.

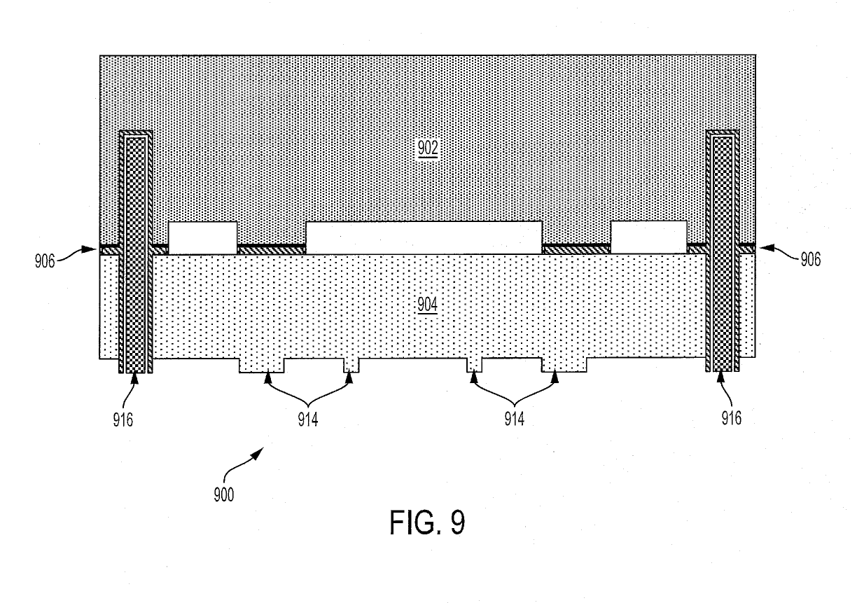

After the conducting material is deposited into the via holes, the manufacturing process of the chip scale package 100 etches a pattern of protrusions into the MEMS device substrate. FIG. 9 illustrates a cross-section view 900 of a MEMS device substrate 904 with a plurality of protrusions in accordance with an embodiment. As in FIG. 8, the MEMS device substrate 904 is bonded to the cap substrate 902 via an oxide layer 906 and also includes a via support structure that has been lined with a liner layer and filled with a conducting material.

In one embodiment, the plurality of protrusions are formed using a patterning and etching process. The patterning and etching process can form a wide array of different size and shaped protrusions. In one embodiment, the plurality of protrusion include a first set of protrusions 914 formed by etching into a body portion of the MEMS device substrate 904 and further include a second set of protrusions 916 formed by etching near the via holes. The first set of protrusions 914 are silicon protrusions and the second set of protrusions 916 are via protrusions.

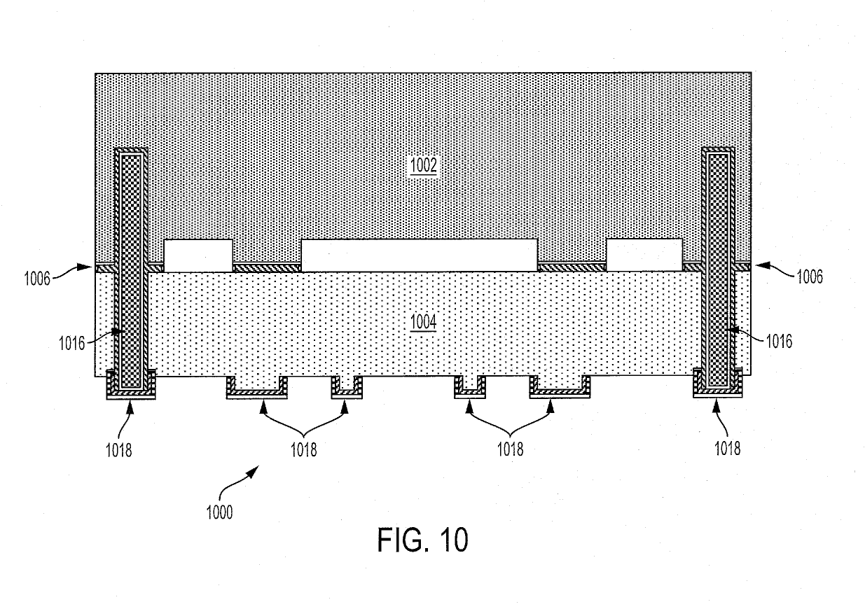

After the plurality of protrusions are formed, the manufacturing process of the chip scale package 100 provides a bonding material on the plurality of protrusions. FIG. 10 illustrates a cross-section view 1000 of a bonding material 1018 provided on a plurality of protrusions in accordance with an embodiment. As in FIG. 9, the MEMS device substrate 1004 is bonded to the cap substrate 1002 via an oxide layer 1006, the via holes have been lined with a liner layer and filled with a conducting material, and a plurality of protrusions have been formed. The plurality of protrusions include silicon protrusions and via protrusions 1016 formed by etching near the via holes.

In FIG. 10, the plurality of protrusions (both the silicon protrusions and the via protrusions) are layered with a bonding material 1018. The bonding material 1018 layering is provided using any of a deposition, patterning, and etching process, or any combination thereof. In one embodiment, the bonding material 1018 is layered on both the silicon and via protrusions and in another embodiment, the bonding material 1018 is selectively applied to only a subset of the plurality of protrusions.

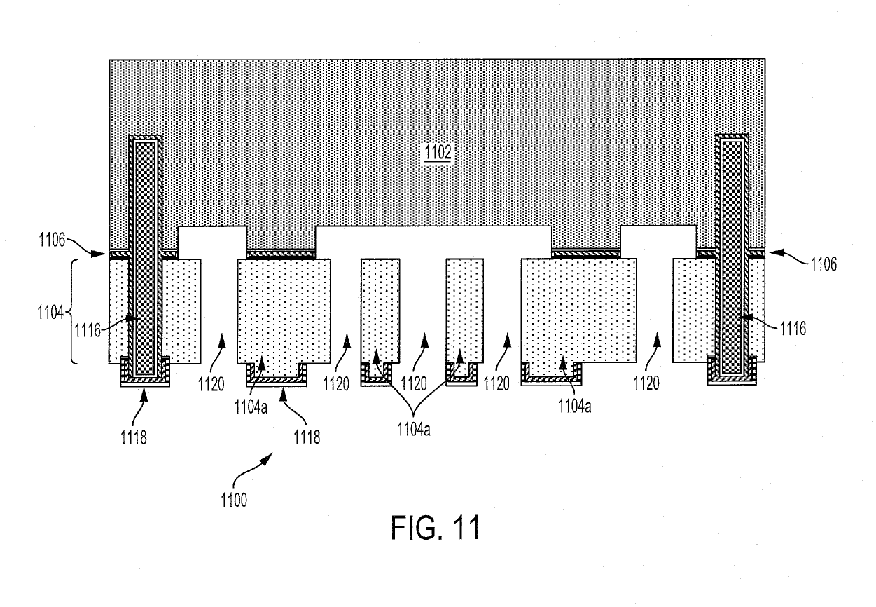

After the bonding material has been applied to the protrusions, the manufacturing process of the chip scale package 100 removes predetermined areas of the MEMS device substrate. FIG. 11 illustrates a cross-section view 1100 of a MEMS device substrate 1104 that has been patterned and etched to remove areas 1120 in accordance with an embodiment. As in FIG. 10, FIG. 11 illustrates the MEMS device substrate 1104 bonded to the cap substrate 1102 via an oxide layer 1106, via holes that have been lined with a liner layer and filled with a conducting material (also referred to as insulated, conducting vias), a plurality of protrusions (including via protrusions 1116) that have been formed, and a bonding material 1118 that has been applied or layered on top of the plurality of protrusions.

The removal of areas 1120 results in the formation of the MEMS device 1104a. The MEMS device 1104a represents the four areas of the inner portion of the MEMS device substrate 1104. The two outer portions of the MEMS device substrate 1104 each surround one of the conducting vias. In one embodiment, the patterning and etching that removes the areas 1120 is a deep reactive ion etch (DRIE) of silicon. In another embodiment, a different patterning and etching process is utilized. One of ordinary skill in the art readily recognizes that a variety of different patterns and MEMS device configurations (other than the one shown in FIG. 11) can be created using the patterning and etching process (e.g., DRIE of silicon) and that would be within the spirit and scope of the present invention.

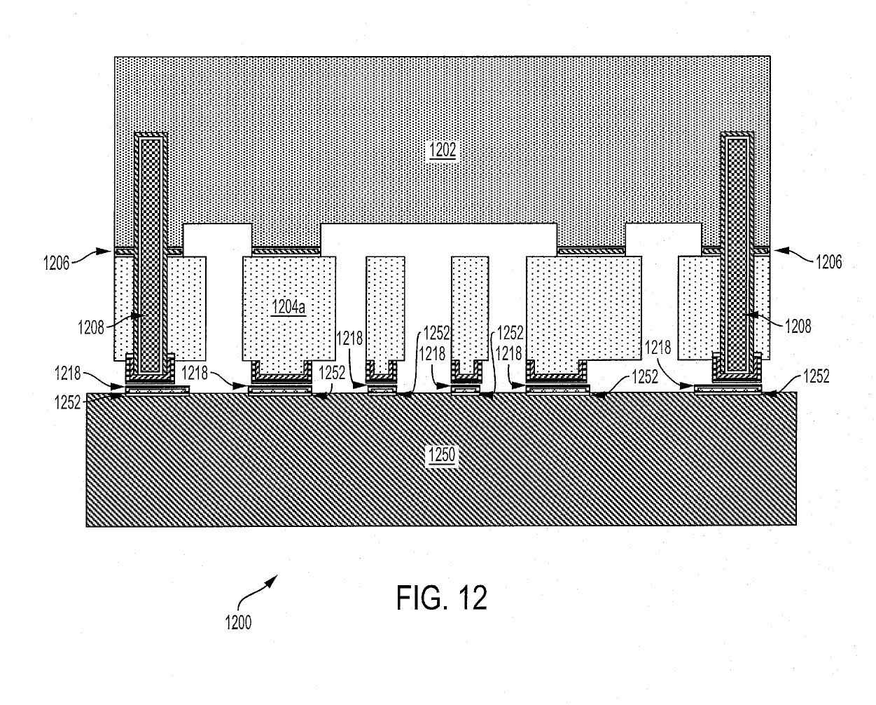

Once the MEMS device has been created by removing the areas of the MEMS device substrate, the manufacturing process of the chip scale package 100 bonds together the substrate with the combination structure that has been formed by bonding the cap substrate and the MEMS device substrate. FIG. 12 illustrates a cross-section view 1200 of a substrate 1250 bonded to both the MEMS device substrate and the cap substrate 1202 in accordance with an embodiment. As in FIG. 11, FIG. 12 illustrates the MEMS device substrate bonded to the cap substrate 1202 via an oxide layer 1206, via holes that have been lined with a liner layer and filled with a conducting material (conducting vias 1208), a plurality of protrusions that have been formed, a bonding material 1218 that has been applied or layered on top of the plurality of protrusions, and the formation of the MEMS device 1204a.

Additionally, in FIG. 12, the substrate 1250 is bonded to the MEMS device substrate via the bonding material 1218 and a plurality of electrodes 1252. Referring back to FIG. 2, the plurality of electrodes 1252 formulate the top layer 252. In one embodiment, the plurality of electrodes 1252 comprise a plurality of metal electrodes. In another embodiment, the plurality of electrodes 1252 comprise a plurality of CMOS electrodes. In one embodiment, the substrate 1250 is a CMOS circuit wafer or substrate that includes a plurality of metal electrodes as the plurality of electrodes 1252. The plurality of metal electrodes form a eutectic with the bonding material 1218 upon sufficient heating to enable eutectic bonding.

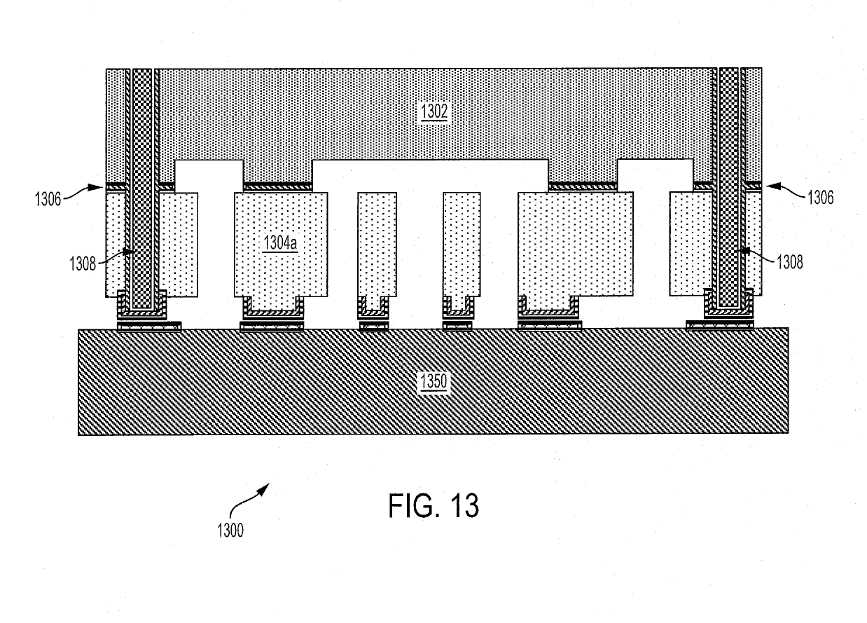

After the substrate is bonded to the MEMS device substrate (and in turn to the cap substrate), the manufacturing process of the chip scale package 100 thins out the substrate and the cap substrate. FIG. 13 illustrates a cross-section view 1300 of a substrate 1350 and a cap substrate 1302 that are thinned in accordance with an embodiment. As in FIG. 12, FIG. 13 illustrates the MEMS device substrate bonded to the cap substrate 1302 via an oxide layer 1306, the conducting vias 1308, the MEMS device substrate bonded to the substrate 1350 via the bonding material 1318 that has been applied or layered on top of the plurality of protrusions of the MEMS device substrate, and the formation of the MEMS device 1304a.

Additionally, in FIG. 13, both the substrate 1350 and the cap substrate 1302 have been thinned to a height that is less than the heights previously illustrated by FIG. 12. In one embodiment, the thinning of the substrate 1350 and the cap substrate 1302 is done by wafer grinding and polishing. The grinding and polishing processes on the cap substrate 1302 exposes the conducting vias 1308 at a top surface of the cap substrate 1302.

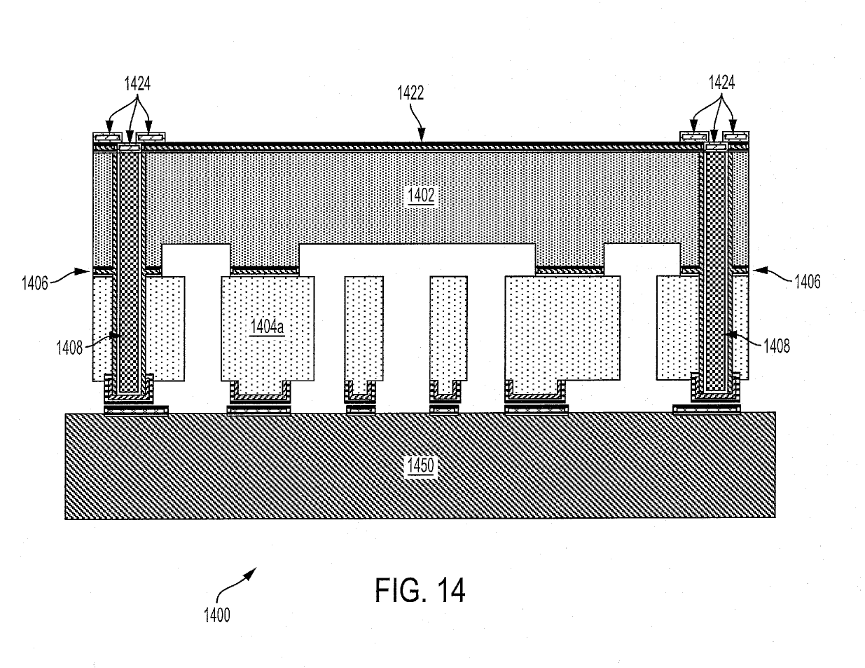

Once the substrate and the cap substrate have been thinned via a grinding and polishing process that exposes the conducting vias at a top surface of the cap substrate, the manufacturing process of the chip scale package 100 prepares for solder ball attachment. FIG. 14 illustrates a cross-section view 1400 of preparing the cap substrate 1402 for solder ball attachment in accordance with an embodiment. As in FIG. 13, FIG. 14 illustrates the MEMS device substrate bonded to the cap substrate 1402 via an oxide layer 1406, the conducting vias 1408, the MEMS device substrate bonded to the substrate 1450 via the bonding material that has been applied or layered on top of the plurality of protrusions of the MEMS device substrate, and the MEMS device 1404a.

Additionally, in FIG. 14, preparation for the solder ball attachment includes depositing and patterning an insulating layer 1422 on the top surface of the cap substrate 1402. In one embodiment, the insulating layer 1422 includes any of silicon nitride and polyimide. After the insulating layer 1422 is layered and patterned, a solder adhesion layer 1424 is patterned and etched on portions of the insulating layer 1422 that are near the exposed areas of the conducting vias 1408.

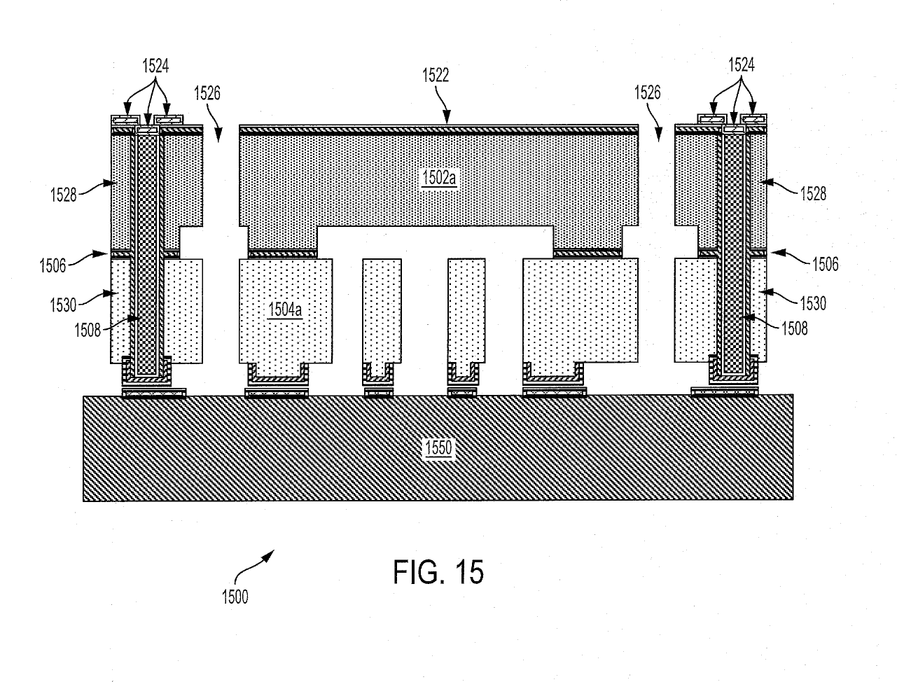

After the insulating and solder adhesion layers are applied, the manufacturing process of the chip scale package 100 provides singulation of the cap substrate to remove predetermined areas. FIG. 15 illustrates a cross-section view 1500 of singulation of the cap substrate in accordance with an embodiment. As in FIG. 14, FIG. 15 illustrates the MEMS device substrate bonded to the cap substrate via an oxide layer 1506, the conducting vias 1508, the MEMS device substrate bonded to the substrate 1550 via the bonding material that has been applied or layered on top of the plurality of protrusions of the MEMS device substrate, the MEMS device 1504a, and the insulating layer 1522 and the solder adhesion layer 1524 that have been applied to a top surface of the cap substrate.

Additionally, in FIG. 15, singulation of the cap substrate has been performed to remove areas 1526 and provide a resulting cap substrate 1502a. In one embodiment, singulation of the cap substrate is performed through any of partial wafer dicing with a saw, laser dicing, and ablation. The singulation of the cap substrate and removal of the areas 1526 provides the via support structure around each of the conducting vias 1508. Each of the via support structures comprises an area 1528 of the cap substrate and an area 1530 of the MEMS device substrate that previously spanned across the entire device.

In addition, the singulation provides a single mechanical connection of the conducting vias 1508 and surrounding support structures (via support structures) through the substrate 1550. As aforementioned, after the areas 1526 are removed from the cap substrate (that previously spanned across the entire device), the resulting cap substrate 1502a is formed. The resulting cap substrate 1502a is bonded to the MEMS device 1504a and the resulting cap substrate 1502a and the MEMS device 1504a are both mechanically isolated from the via support structures.

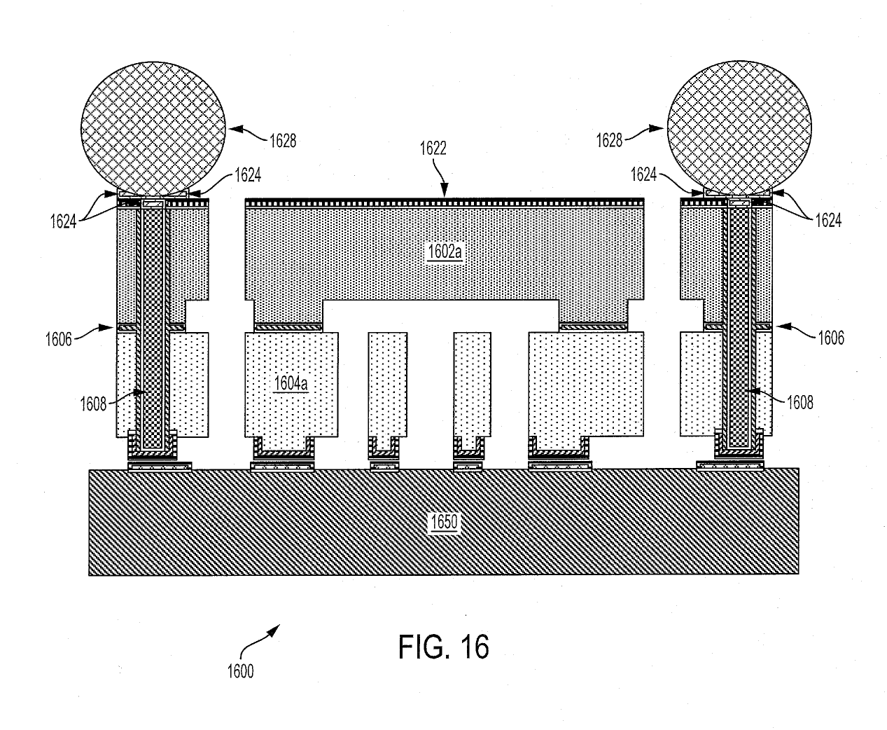

After the singulation of the cap substrate resulting in certain removed areas, the manufacturing process of the chip scale package 100 attaches the solder balls. FIG. 16 illustrates a cross-section view 1600 of solder ball attachment in accordance with an embodiment. As in FIG. 15, FIG. 16 illustrates the MEMS device substrate bonded to the cap substrate via an oxide layer 1606, the conducting vias 1608, the MEMS device substrate bonded to the substrate 1650 via the bonding material that has been applied or layered on top of the plurality of protrusions of the MEMS device substrate, the MEMS device 1604a, and the insulating layer 1622 and the solder adhesion layer 1624 that have been applied to a top surface of the cap substrate, and the singulation of the cap substrate.

Additionally, in FIG. 16, a plurality of solder balls 1628 (two are pictured in FIG. 16 but the chip scale package 100 could include more than two solder balls) have been attached to the cap substrate portion of the via support structures via the solder adhesion layer 1624. Therefore, the resulting cap substrate 1602a (formed after the singulation of the cap substrate as shown in FIG. 15) and the MEMS device 1604a (formed after the etching as shown in FIG. 11) are both mechanically isolated from the attached solder balls and not in direct contact with the conducting vias 1608.

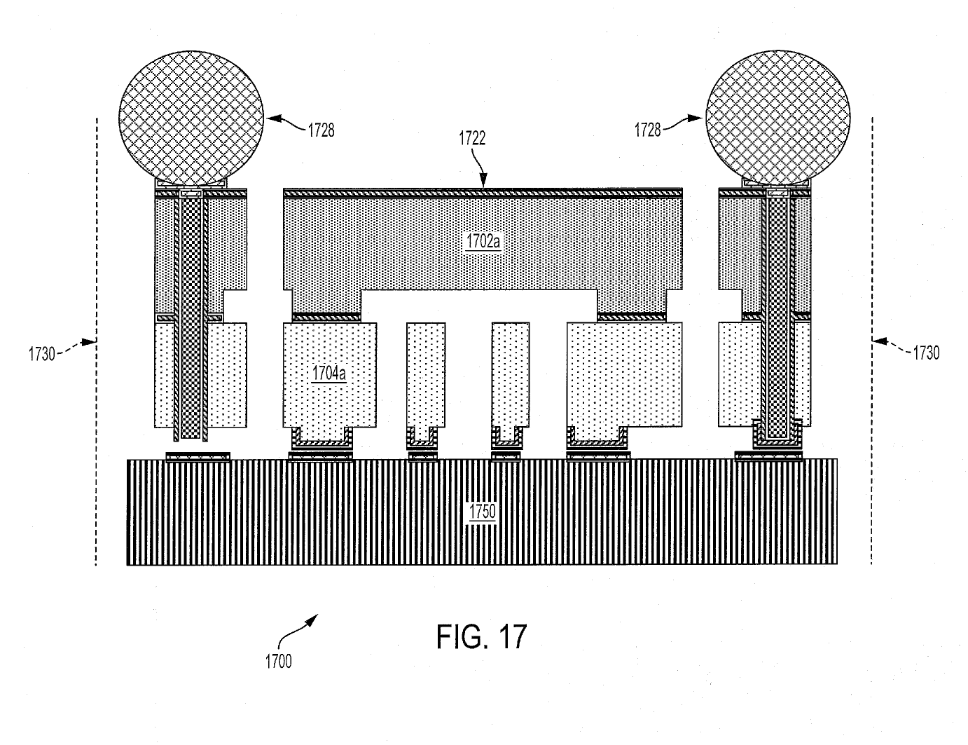

After the solder balls have been attached, the manufacturing process of the chip scale package 100 provides singulation of the substrate and the chip scale package. FIG. 17 illustrates a cross-section view 1700 of singulation of the substrate 1750 and chip scale package 100 in accordance with an embodiment. As in FIG. 16, FIG. 17 illustrates the resulting cap substrate 1702a bonded to the MEMS device 1704a, the insulating layer 1722 and the solder adhesion layer that have been applied to a top surface of the cap substrate, and the attachment of the plurality of solder balls 1728 to a portion of the cap substrate near the conducting vias (and surrounding via support structures). Additionally, in FIG. 17, singulation of the substrate 1750 and chip scale package is indicated by the dotted lines 1730. Singulation of the substrate 1750 is performed using any of wafer dicing with a saw, laser dicing, and ablation. The additional singulation separates the chip scale package and MEMS device from additional devices manufactured in a similar process.

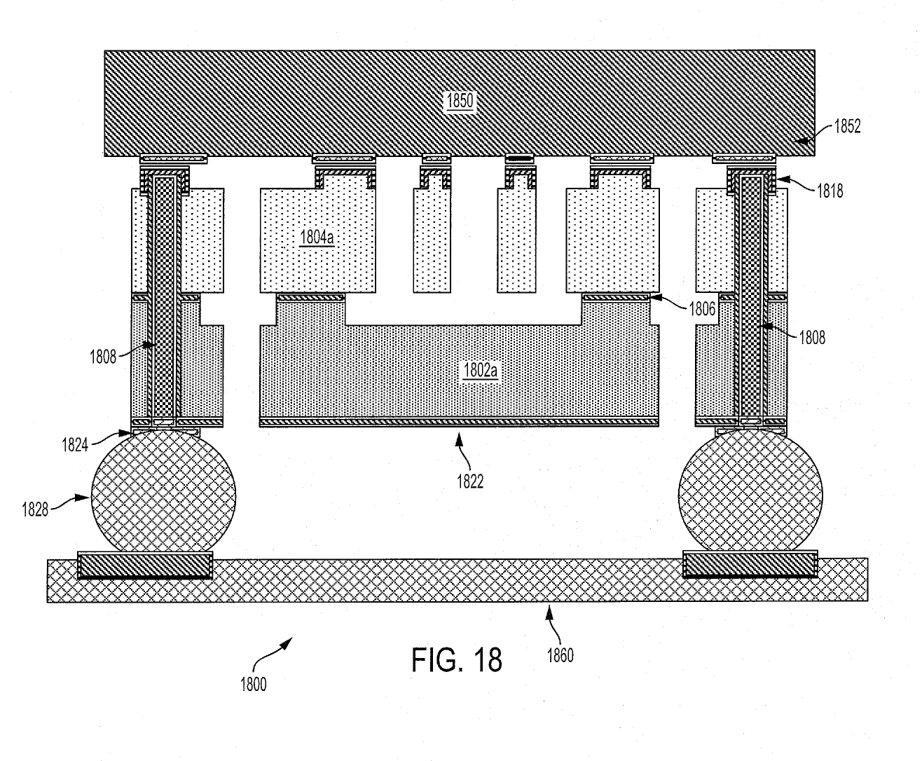

After the singulation of the substrate and the chip scale package, the manufacturing process of the chip scale package 100 attaches the chip scale package 100 for the MEMS device to a printed circuit board. FIG. 18 illustrates a cross-section view 1800 of attaching the chip scale package 100 to a printed circuit board 1860 in accordance with an embodiment. FIG. 18 illustrates the chip scale package 100 as illustrated by FIG. 1. FIG. 18 illustrates a cap substrate 1802a bonded to a MEMS device 1804a via a bonding layer 1806. The MEMS device 1804a is bonded to the substrate 1850 via a bonding layer 1818 and a plurality of electrodes 1852. The device includes two via support structures that surround the conducting vias 1808 and are bonded to the solder balls 1828 through the use of an insulating layer 1822 and a solder adhesion layer 1824. The solder balls 1828 are bonded to a printed circuit board 1860.

In one embodiment, the chip scale package (CSP) of the MEMS device that is formulated comprises a substrate, a cap substrate, a MEMS device substrate bonded to and located between both the substrate and the cap substrate, at least one solder ball, and a via support structure coupled to both the at least one solder ball and the substrate, wherein the MEMS device substrate and the cap substrate are mechanically isolated from the at least one solder ball.

In this embodiment, the via support structure includes at least one insulated, conducting via therethrough to provide an electrical connection to the substrate. The at least one insulated via therethrough electrically connects at least one electrode on the substrate with the at least one solder ball. The at least one insulated via therethrough includes any of polysilicon, tungsten, aluminum, and copper as the conducting material that provides the electrical connection.

In this embodiment, the via support structure is coupled to the at least one solder ball via an adhesion layer. The substrate comprises any of a semiconductor wafer and a laminate. The semiconductor wafer can be a CMOS wafer. The at least one solder ball is electrically connected to the laminate by the via support structure. The via support structure can comprise silicon. The MEMS device substrate is bonded to the substrate using any of bonding material, metal electrodes, and a combination thereof. The MEMS device substrate includes a MEMS device sealed within the substrate and the cap substrate and thus also mechanically isolated from the at least one solder ball which protects against degradation and external forces.

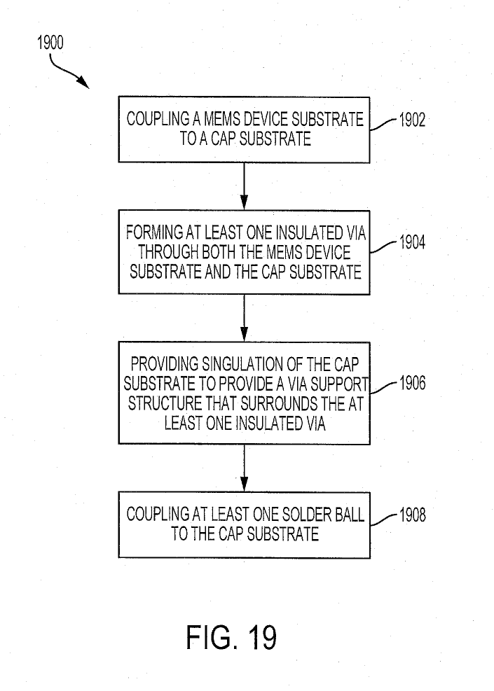

FIG. 19 illustrates a method 1900 for providing a chip scale package of a MEMS device in accordance with an embodiment. The method 1900 comprises coupling a MEMS device substrate to a cap substrate, via step 1902, forming at least one insulated via through both the MEMS device substrate and the cap substrate, via step 1904, providing singulation of the cap substrate to provide a via support structure that surrounds the at least one insulated via, via step 1906, and coupling at least one solder ball to the via support structure, via step 1908.

In one embodiment, the method 1900 further comprises forming the MEMS device from the MEMS device substrate by patterning and etching the MEMS device substrate. In one embodiment, the patterning and etching is a deep reactive ion etch (DRIE) of silicon. In another embodiment, the patterning and etching is performed using other etching techniques.

In one embodiment, the method 1900 further comprises coupling both the MEMS device substrate and the cap substrate to a substrate, wherein the substrate includes a metal layer comprising a plurality of electrodes. In one embodiment, the method 1900 further comprises etching a plurality of recesses into the MEMS device substrate to form a plurality of protrusions on the MEMS device substrate and depositing a bonding material to the plurality of protrusions, wherein the MEMS device substrate is bonded to the substrate via the bonding material and the metal layer. By bonding the MEMS device substrate to the substrate, the cap substrate is also in turn coupled to the substrate as well.

In one embodiment, the method 1900 further comprises etching a plurality of recesses into the cap substrate to form a plurality of protrusions on the cap substrate and depositing an oxide layer on the plurality of protrusions. In one embodiment, the forming of the at least one insulated via further comprises etching at least one via hole through the MEMS device substrate, through an oxide layer that couples the MEMS device substrate and the cap substrate together, and into the cap substrate, depositing a liner insulating layer within the at least one via hole, and depositing a conducting material within the at least one via hole.

In one embodiment, the providing singulation provides a via support structure that surrounds the at least one conducting via, further wherein the at least one solder ball is coupled to via support structure (near the cap substrate portion of the via support structure) by using an insulation layer and an adhesion layer.

As above described, a system and method in accordance with the present invention provide a chip scale package or MEMS device packaging that increases MEMS device performance and reduces potential damage from external factors including but not limited to handling issues and shear stress. The chip scale package mechanically isolates the cap substrate and the MEMS device substrate from the solder balls that are electrically connected to the substrate by a via support structure. Therefore, a MEMS device of the MEMS device substrate that is sealed within the cap structure and the substrate is also mechanically isolated and thereby protected from external forces like shear stress which can cause damage to the MEMS device. The chip scale package also provides a thinner total package height compared to conventional packaging techniques.

Although the present invention has been described in accordance with the embodiments shown, one of ordinary skill in the art will readily recognize that there could be variations to the embodiments and those variations would be within the spirit and scope of the present invention. Accordingly, many modifications may be made by one of ordinary skill in the art without departing from the spirit and scope of the appended claims.

1. A chip scale package (CSP), comprising:
a substrate;
a cap substrate;
a micro-electro-mechanical system (MEMS) device substrate bonded to and located between both the substrate and the cap substrate;
at least one solder ball; and
a via support structure coupled to both the at least one solder ball and the substrate, wherein the MEMS device substrate and the cap substrate are mechanically isolated from the at least one solder ball.

2. The CSP of claim 1, wherein the via support structure includes at least one insulated via therethrough to provide an electrical connection to the substrate.

3. The CSP of claim 2, wherein the at least one insulated via therethrough electrically connects at least one electrode on the substrate with the at least one solder ball.

4. The CSP of claim 2, wherein the at least one insulated via therethrough comprises any of polysilicon, tungsten, aluminum, and copper.

5. The CSP of claim 1, wherein the via support structure is coupled to the at least one solder ball via an adhesion layer.

6. The CSP of claim 1, wherein the substrate comprises a semiconductor wafer.

7. The CSP of claim 1, wherein the semiconductor wafer is a complementary metal-oxide semiconductor (CMOS) wafer.

8. The CSP of claim 1, wherein the substrate comprises a laminate.

9. The CSP of claim 8, wherein the at least one solder ball is electrically connected to the laminate by the via support structure.

10. The CSP of claim 1, wherein the via support structure comprises silicon.

11. The CSP of claim 1, wherein the MEMS device substrate is bonded to the substrate using any of bonding material, metal electrodes, and a combination thereof.

12. The CSP of claim 1, wherein the MEMS device substrate includes a MEMS device sealed within the substrate and the cap substrate.

13. A method for providing a chip scale package of a MEMS device, the method comprising:
coupling a MEMS device substrate to a cap substrate;
forming at least one insulated via through both the MEMS device substrate and the cap substrate;
singulating the cap substrate and the MEMS device substrate to provide a via support structure that surrounds the at least one insulated via; and
coupling at least one solder ball to the via support structure.

14. The method of claim 13, further comprising:
forming the MEMS device from the MEMS device substrate by patterning and etching the MEMS device substrate.

15. The method of claim 14, wherein the patterning and etching is a deep reactive ion etch (DRIE) of silicon.

16. The method of claim 13, further comprising:
coupling both the MEMS device substrate and the cap substrate to a substrate, wherein the substrate includes a metal layer comprising a plurality of electrodes.

17. The method of claim 16, further comprising:
etching a plurality of recesses into the MEMS device substrate to form a plurality of protrusions on the MEMS device substrate; and
depositing a bonding material to the plurality of protrusions on the MEMS device substrate, wherein the MEMS device substrate is bonded to the substrate via the bonding material and the metal layer.

18. The method of claim 13, further comprising:
etching a plurality of recesses into the cap substrate to form a plurality of protrusions on the cap substrate; and
depositing an oxide layer on the plurality of protrusions on the cap substrate.

19. The method of claim 13, wherein the forming of the at least one insulated via further comprises:
etching at least one via hole through the MEMS device substrate, through an oxide layer that couples the MEMS device substrate and the cap substrate together, and into the cap substrate;
depositing a liner insulating layer within the at least one via hole; and
depositing a conducting material within the at least one via hole.

20. The method of claim 13, wherein the at least one solder ball is coupled to the via support structure by using an insulation layer and an adhesion layer.
